(19) United States
(12) Patent Application Publication
(10) Pub. No.: US 2014/0320110 A1
(43) Pub. Date: Oct. 30, 2014

(54) MEASURING APPARATUS, MEASURING METHOD, AND MEASURING PROGRAM

(71) Applicant: NIHON DEMPA KOGYO CO., LTD., TOKYO (JP)

(72) Inventors: HIROKI MATSUI, SAITAMA (JP); KAZUNORI HASEGAWA, SAITAMA (JP)

(73) Assignee: NIHON DEMPA KOGYO CO., LTD., TOKYO (JP)

(21) Appl. No.: 14/258,028

(22) Filed: Apr. 22, 2014

(30) Foreign Application Priority Data
Apr. 26, 2013 (JP) 2013-093690

(51) Int. Cl. G01R 23/02

(52) U.S. Cl. CPC G01R 23/02
USPC 324/76.77

(57) ABSTRACT

A measuring apparatus for measuring a characteristic of a crystal unit includes an input unit, a measuring unit, a storage unit, and a calibrating unit. The input unit is configured to input a measurement signal into the crystal unit. The measuring unit is configured to measure the characteristic of the crystal unit based on an output signal output from the crystal unit with respect to the measurement signal. The storage unit is configured to associate calibration data with a measuring condition to measure the characteristic of the crystal unit, and store the associated data. The calibration data is generated based on a measurement result measured by the measuring unit with connecting a short-circuit element instead of the crystal unit. The calibrating unit is configured to calibrate the characteristic of the crystal unit measured by the measuring unit based on the calibration data.

### CROSS REFERENCE TO RELATED APPLICATIONS

This application claims the priority benefit of Japan application serial no. 2013-093690, filed on Apr. 26, 2013. The entirety of the above-mentioned patent application is hereby incorporated by reference herein and made a part of this specification.

### TECHNICAL FIELD

This disclosure relates to a measuring apparatus, a measuring method, and a measuring program that measure characteristics of a crystal unit.

### DESCRIPTION OF THE RELATED ART

A measuring apparatus is conventionally known that measures characteristics of an electronic device such as a crystal unit and a semiconductor device (see Japanese Unexamined Patent Application Publication Nos. 2008-233053 and 2006-189328). The conventional measuring apparatus calibrates the measured data using calibration data generated in advance.

Incidentally, the characteristics of a crystal unit is measured with frequency sweep by sequentially shifting a frequency of a measurement signal input into the crystal unit, which is a measurement object, to measure a gain characteristic and a phase characteristic of the crystal unit based on the input signal input into the crystal unit and an output signal output from the crystal unit. Changing measurement timing of a level and a phase of the output signal or changing a frequency of the measurement signal causes a variation in the phase of the output signal at the timing when the level and the phase of the output signal are measured. Accordingly, for the high accuracy measurement, eliminating the influence of the phase variation requires calibration for every time when a measurement timing of the level and the phase of the output signal or the frequency of the measurement signal changes, thus the measurement of the characteristics of the crystal unit takes long time.

A need thus exists for a measuring apparatus, a measuring method, and a measuring program which are not susceptible to the drawback mentioned above.

### SUMMARY

A measuring apparatus for measuring a characteristic of a crystal unit according to the disclosure includes an input unit, a measuring unit, a storage unit, and a calibrating unit. The input unit is configured to input a measurement signal into the crystal unit. The measuring unit is configured to measure the characteristic of the crystal unit based on an output signal output from the crystal unit with respect to the measurement signal. The storage unit is configured to associate calibration data with a measuring condition to measure the characteristic of the crystal unit, and store the associated data. The calibration data is generated based on a measurement result measured by the measuring unit with connecting a short-circuit element instead of the crystal unit. The calibrating unit is configured to calibrate the characteristic of the crystal unit measured by the measuring unit based on the calibration data.

### BRIEF DESCRIPTION OF THE DRAWINGS

The foregoing and additional features and characteristics of this disclosure will become more apparent from the following detailed description considered with reference to the accompanying drawings.

FIG. 1 is a block diagram illustrating an outline of a measuring system according to a first embodiment of the disclosure.

FIG. 2 is a functional block diagram illustrating the measuring system according to the first embodiment of the disclosure.

FIG. 3 is a flowchart illustrating a process of the measuring apparatus according to the first embodiment of the disclosure.

FIG. 4 is a diagram illustrating characteristic data of a crystal unit measured by a measuring unit according to the first embodiment of the disclosure.

FIG. 5 is a diagram illustrating characteristic data of the crystal unit measured by a measuring unit according to a second embodiment of the disclosure.

### DETAILED DESCRIPTION

### Outline of Measuring System S According to First Embodiment

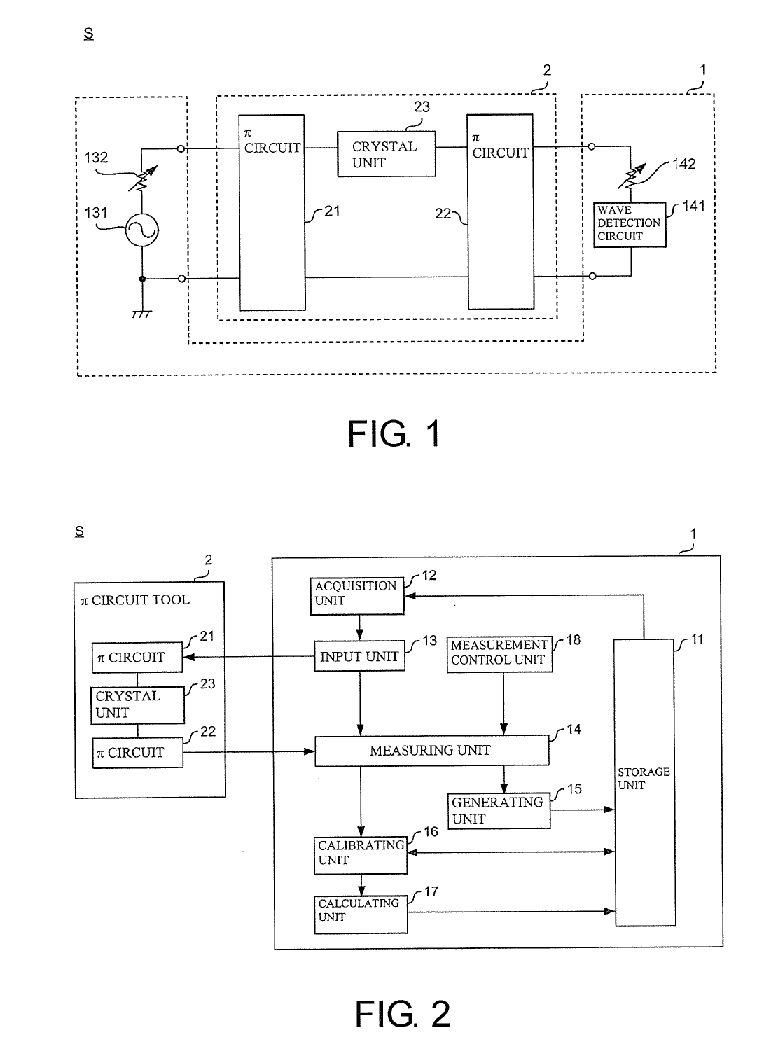

FIG. 1 is a diagram illustrating an outline of a measuring system S according to the embodiment. The measuring system S includes a measuring apparatus 1 and a π circuit tool 2 to which a crystal unit 23 is mounted.

The measuring apparatus 1 includes a signal source 131, a variable resistor 132, a wave detection circuit 141, and a variable resistor 142. The measuring apparatus 1 measures a frequency characteristic of the crystal unit 23 by inputting a measurement signal output from the signal source 131 into the crystal unit 23 mounted to the π circuit tool 2, and detecting an output signal output from the crystal unit 23 using the wave detection circuit 141. The measuring apparatus 1 calibrates characteristic data indicating the measured gain characteristic and phase characteristic of the crystal unit 23 based on calibration data stored in advance, and calculates equivalent circuit constant of the crystal unit 23 based on the calibrated characteristic data of the crystal unit 23. The it circuit tool 2 includes it circuits 21 and 22 respectively located at the input side and the output side of the it circuit tool 2. A measurement object such as the crystal unit 23 is mounted between the π circuit 21 and the π circuit 22.

The following describes a particular functional configuration of the measuring apparatus 1. FIG. 2 is a functional block diagram illustrating the measuring system S according to the embodiment. As shown in FIG. 2, the measuring apparatus 1 includes a storage unit 11, an acquisition unit 12, an input unit 13, a measuring unit 14, a generating unit 15, a calibrating unit 16, a calculating unit 17, and a measurement control unit 18.

The storage unit 11 includes, for example, a memory such as a RAM and a ROM. The storage unit 11 stores the calibration data of a measuring system, which is generated based on a measurement result measured by the measuring unit 14 with connecting a short-circuit element instead of the crystal unit 23 in the π circuit tool 2. Also, the storage unit 11 stores measuring conditions for measuring the characteristics of the crystal unit 23. Examples of the measuring conditions include a frequency of the measurement signal, a level of the measurement signal, and a time interval with which the frequency of the measurement signal changes. The storage unit 11 stores the characteristic data of the crystal unit 23 measured by the measuring unit 14 as calibrated information.

The acquisition unit 12 refers to the storage unit 11 to acquire the measuring conditions which are conditions for measuring the characteristics of the crystal unit 23. Specifically, the acquisition unit 12 acquires, from the storage unit 11, at least one of a frequency of the measurement signal, a level of the measurement signal, and a time interval with which the frequency of the measurement signal changes as the measuring conditions.

The input unit 13 includes the signal source 131 and the variable resistor 132. The input unit 13 inputs a measurement signal into the crystal unit 23 mounted to the π circuit tool 2 based on the measuring conditions acquired by the acquisition unit 12. For example, the input unit 13 sequentially inputs a plurality of the measurement signals, whose frequencies change per a first period of time, into the crystal unit 23. The first period of time is, for example, 10μ seconds. Also, the input unit 13 sequentially inputs a plurality of the measurement signals, whose levels change with time, into the crystal unit 23.

The measuring unit 14 includes the wave detection circuit 141, the variable resistor 142, an A/D converter circuit, and an integrator. The measuring unit 14 measures the characteristics of the crystal unit 23 such as a phase characteristic and a gain characteristic of the crystal unit 23 based on the output signal, which is relative to the measurement signal, output from the crystal unit 23. Namely, the measuring unit 14 measures the gain characteristic and the phase characteristic or similar characteristics of the output signal acquired from the it circuit 22.

The measuring unit 14 mixes an input signal received from the input unit 13 and an output signal received from the it circuit 22, and converts the mixed signal from analog to digital using the A/D converter circuit. Then, the measuring unit 14 measures a gain of the output signal by integrating the digital signal output from the A/D converter circuit using the integrator. The measuring unit 14 causes the storage unit 11 to sequentially store the measurement results.

The generating unit 15 generates the calibration data based on the characteristics of the measuring system measured by the measuring unit 14. First, the generating unit 15 receives characteristic data of the measuring system indicating the characteristics of the measuring system, which is measured by the measuring unit 14 with connecting the short-circuit element instead of the crystal unit 23 in the π circuit tool 2 and with changing the measuring conditions. Specifically, the generating unit 15 receives, from the measuring unit 14, a piece of data indicating a level of the input signal input into the π circuit 21 and a piece of data indicating a level of the output signal output from the π circuit 22, both of the pieces of data being associated with each of a plurality of the measuring conditions.

Subsequently, the generating unit 15 calculates an increase/decrease ratio of the level of the output signal to the level of the input signal for each measuring condition. The generating unit 15 generates the calibration data corresponding to the measuring conditions from the increase/decrease ratio calculated for each measuring condition. The generating unit 15 functions as a storage control unit configured to associate the generated calibration data with the measuring conditions, and cause the storage unit 11 to store the associated calibration data.

The calibrating unit 16 calibrates the characteristic data of the crystal unit 23 measured by the measuring unit 14, based on the calibration data stored in the storage unit 11. For example, the calibrating unit 16 receives, from the storage unit 11, the calibration data corresponding to the measuring conditions with which the measuring unit 14 has measured, and calibrates the characteristic data of the crystal unit 23 measured by the measuring unit 14 by multiplying the measured characteristic data by the received calibration data.

The calculating unit 17 calculates the equivalent circuit constants of the crystal unit 23 based on the calibrated information stored in the storage unit 11. For example, the calculating unit 17 calculates the equivalent circuit constants per a second period of time, which is equal to or longer than a first period of time. The first period of time is a time interval with which the frequency of the measurement signal changes. Specifically, the calculating unit 17 identifies the parallel resonance frequency and the series resonance frequency based on the characteristic data corresponding to the calibrated information, and calculates an equivalent series resistance, an equivalent series inductance, an equivalent series capacitance and a Q-value of the crystal unit 23. The calculating unit 17 causes the storage unit 11 to store the calculated equivalent circuit constants.

The measurement control unit 18 determines whether or not the characteristics of the crystal unit measured by the measuring unit 14 fulfill the predetermined condition per the second period of time, which is equal to or longer than the first period of time, and causes the measuring unit 14 to stop the measurement when the characteristics of the crystal unit fulfill the predetermined condition. For example, the measurement control unit 18 determines whether or not a piece of data showing, as the predetermined condition, the phase among the equivalent circuit constants indicates 0° and causes the measuring unit 14 to stop the measurement when the piece of data fulfills the predetermined condition.

### Operation of Measuring Apparatus 1

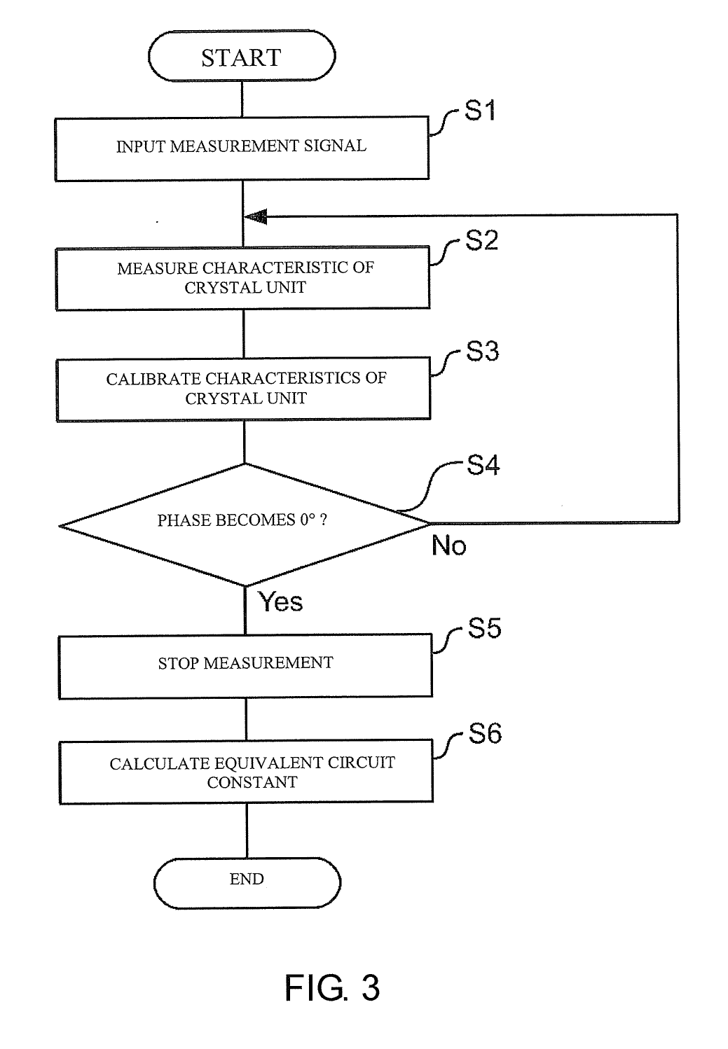

The following describes a processing flow of the measuring apparatus 1. FIG. 3 is a flowchart illustrating a process of the measuring apparatus 1 according to the embodiment of the disclosure. The input unit 13 inputs a measurement signal into the crystal unit 23 mounted to the m circuit tool 2 based on the measuring conditions acquired by the acquisition unit 12 (S1).

Subsequently, the measuring unit 14 measures the characteristics of the crystal unit 23 based on the output signal, which is relative to the measurement signal, output from the crystal unit 23 (S2). The measuring unit 14 causes the storage unit 11 to sequentially store the measured characteristics of the crystal unit 23. Subsequently, the calibrating unit 16 calibrates the characteristics of the crystal unit 23 measured by the measuring unit 14, based on the calibration data stored in the storage unit 11 (S3). The calibrating unit 16 causes the storage unit 11 to store, as calibrated information, the calibrated characteristic data indicating the characteristics of the crystal unit 23.

Subsequently, the measurement control unit 18 determines whether or not a value of the phase becomes 0°, based on the calibrated information stored in the storage unit 11 (S4). The measuring unit 14 stops the measurement (S5) if the data of the phase indicates 0°, while the process proceeds to step S2 if the data does not indicate 0°. After the measuring unit 14 stops the measurement, the calculating unit 17 calculates the equivalent circuit constants of the crystal unit 23 based on the calibrated information stored in the storage unit 11 (S6). The equivalent circuit constants calculated by the calculating unit 17 is, for example, displayed on a monitor connected to the measuring apparatus 1.

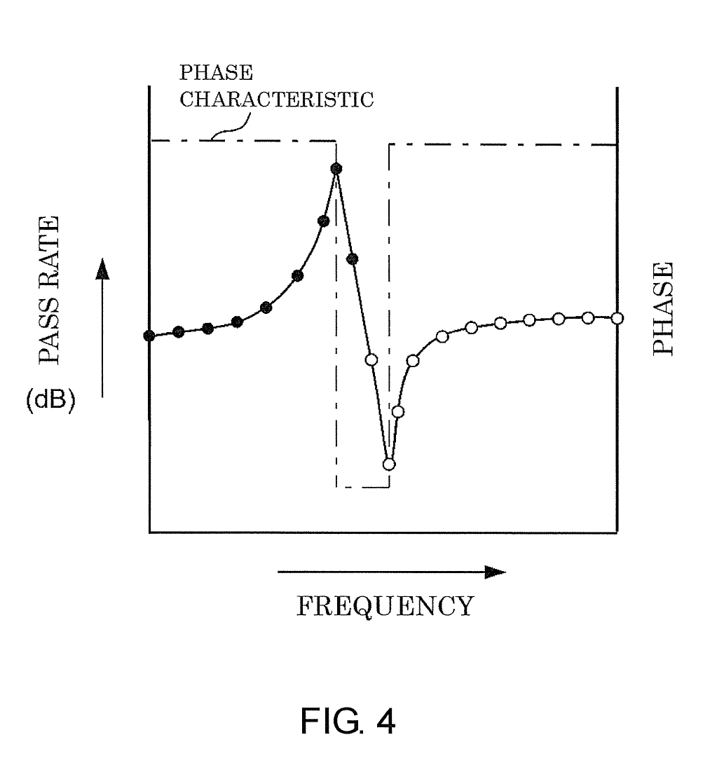

FIG. 4 is a diagram illustrating the characteristic data of the crystal unit 23 measured by the measuring unit 14. FIG. 4 illustrates the characteristic data calibrated by the calibrating unit 16. The horizontal axis of FIG. 4 shows a frequency of the measurement signal. The solid line in FIG. 4 shows the level of the output signal output from the π circuit 22, and the one-dot chain line shows the phase of the output signal output from the π circuit 22. The phase of the output signal changes from the maximum value to the minimum value at near the series resonance frequency where the level of the output signal is the maximum, while the phase changes from the minimum value to the maximum value at near the parallel resonance frequency where the level of the output signal is the minimum.

In an example shown in FIG. 4, the input unit 13 inputs, with the predetermined time intervals, measurement signals, whose frequencies rise with the predetermined frequency intervals, into the π circuit 21. The measuring unit 14 measures the level and the phase of the output signal output from the π circuit 22 for every time when the frequency of the measurement signal changes. When the level of the output signal increases and then decreases, as well as the phase of the output signal becomes 0°, the measuring unit 14 will stop the measurement after the measuring unit 14 further measures at the predetermined number of different frequency points. The black points in FIG. 4 show frequency points at which the measuring unit 14 has measured the output signal, while the white points show frequency points at which the measuring unit 14 has not measured the output signal.

In the example shown in FIG. 4, the measuring unit 14 needs to measure at 20 frequency points if the measuring unit 14 did not stop the measurement at the point when the phase became 0°. The measuring unit 14, however, measures at one more frequency point after the phase becomes 0° then stops the measurement, accordingly the measuring unit 14 measures at nine frequency points. In this way, the measuring apparatus 1 can significantly reduce the time for measuring the characteristics of the crystal unit.

### Effect of First Embodiment

As described above, in the measuring apparatus 1 according to the first embodiment, the measuring unit 14 measures the characteristics of the crystal unit 23 based on the output signal output, which is relative to a measurement signal, from the crystal unit 23, and the calibrating unit 16 calibrates the characteristic data, which indicates the characteristics of the crystal unit 23, measured by measuring unit 14 based on the calibration data. Thus, the measuring apparatus 1 calibrates the characteristic data of the crystal unit 23 based on the calibration data stored in advance. Accordingly, the measuring apparatus 1 does not need to measure with calibrating for every time when the measuring conditions change.

In addition, in the measuring apparatus 1, the calculating unit 17 calculates the equivalent circuit constants of the crystal unit 23 based on the calibrated information. Accordingly, the calculating unit 17 can calculate the equivalent circuit constants of the crystal unit 23 without calibrating for every time when the measuring conditions change. Also, in the measuring apparatus 1, the input unit 13 inputs the measurement signal based on the measuring conditions stored in the storage unit 11, and the calibrating unit 16 calibrates the measurement result using the calibration data corresponding to the measuring conditions. Accordingly, the calibrating unit 16 can surely calibrate the measurement result without removing the crystal unit 23 from the π circuit tool 2 even if the measuring conditions change.

In addition, the storage unit 11 of the measuring apparatus 1 stores at least one of a frequency of the measurement signal, a level of the measurement signal, and a time interval with which the frequency of the measurement signal changes as the measuring conditions. Accordingly, the measuring apparatus 1 can obtain the measurement result based on these measuring conditions.

Also, in the measuring apparatus 1, the input unit 13 sequentially inputs a plurality of the measurement signals, whose frequencies change per the first period of time, into the crystal unit 23, and the measurement control unit 18 determines, per the second period of time, whether or not the characteristics measured by the measuring unit 14 fulfill the predefined conditions, and stops the measurement when the characteristics of the crystal unit fulfill the predetermined condition. Thus, the measuring apparatus 1 can cause the measuring unit 14 to stop the measurement when the characteristics of the crystal unit fulfill the predetermined condition, and start the next measurement. Accordingly, the measuring apparatus 1 can further reduce the time for measuring the characteristics of the crystal unit 23.

The measuring apparatus 1 can perform measurement within a frequency range narrower than that of a conventional measuring apparatus based on the calibration data stored in advance. Accordingly, the measuring apparatus 1 can significantly reduce the measurement time especially when measuring a crystal unit having a high Q-value or carrying out a Drive Level Dependence (DLD) test in which measurement is performed several times with changing the drive levels.

### Second Embodiment

In the first embodiment, the described measuring apparatus 1 measures the characteristics of the crystal unit 23 by performing frequency sweep with the predetermined frequency intervals. In contrast to this, the measuring apparatus 1 according to the second embodiment is different in that the measuring apparatus 1 measures the characteristics of the crystal unit 23 by performing frequency sweep with first frequency intervals then performing another frequency sweep with second frequency intervals that are shorter than the first frequency intervals.

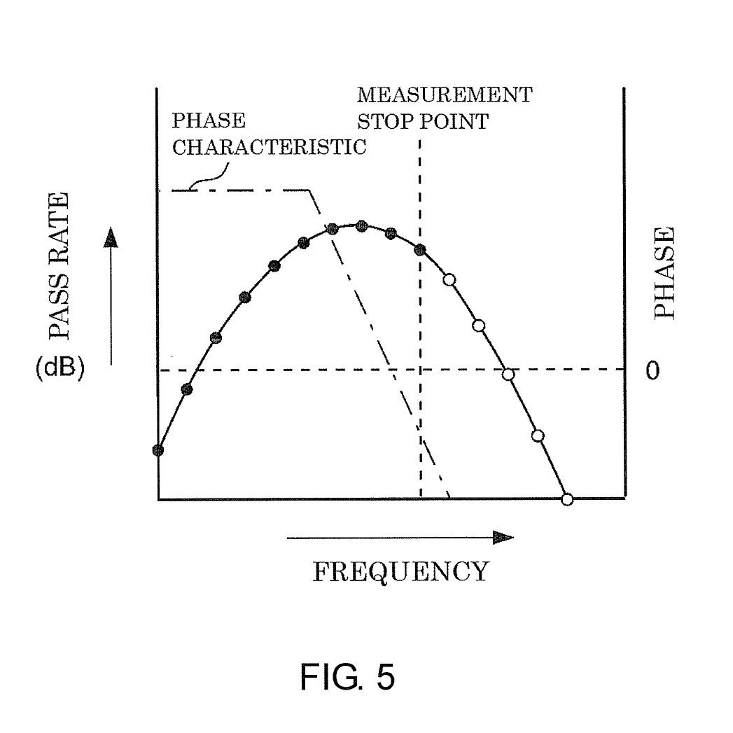

FIG. 5 is a diagram illustrating the characteristic data of the crystal unit 23 measured by the measuring unit 14 according to the second embodiment. FIG. 5 shows the characteristic data obtained by measuring the characteristics of the crystal unit 23 within a frequency range near a point at which the gain indicates the maximum value in the characteristic data of the crystal unit 23 shown in FIG. 4. The characteristic data shown in FIG. 5 is measured with frequency intervals shorter than the frequency intervals with which the characteristic data shown in FIG. 4 are measured.

The input unit 13 inputs a first measurement signal, whose frequency changes with the first intervals, to the n circuit tool 2. The measuring unit 14 measures the characteristics of the crystal unit 23 using the output signal output from the crystal unit 23 when the first measurement signal is input into the crystal unit 23, and stops the measurement when the characteristic data calibrated by the calibrating unit 16 fulfills the predetermined conditions. The measuring unit 14 stops the measurement, for example, at the point when the gain of the output signal decreases and then increases as well as the phase of the output signal becomes 0°. The calculating unit 17 calculates the parallel resonance frequency based on the characteristic data calibrated by the calibrating unit 16.

Subsequently, the input unit 13 inputs a second measurement signal, which is included in the characteristic data obtained based on the first measurement signal and changes with the second intervals within the predetermined frequency range, into the π circuit tool 2. The measuring unit 14 measures a level and a phase of an output signal output from the crystal unit 23 when the second measurement signal is input into the crystal unit 23. The measuring unit 14 stops the measurement when the phase of the output signal becomes 0°. The calculating unit 17 calculates the series resonance frequency based on the characteristic data calibrated by the calibrating unit 16.

### Effect of Second Embodiment

The measuring apparatus 1 according to the second embodiment first measures the characteristics of the crystal unit 23 with the first frequency intervals, then measures the characteristics of the crystal unit 23 with the second frequency intervals, which are shorter than the first frequency intervals, within the predetermined frequency range when the characteristics of the crystal unit 23 fulfill the predefined condition. Thus, according to the second embodiment, the measuring apparatus 1 can narrow down the frequency range for measuring with high accuracy which requires more measurement time. Accordingly, the measuring apparatus 1 can successfully reduce measurement time while measuring with high accuracy.

In addition, the calculating unit 17 calculates the parallel resonance frequency, which does not require high accuracy, based on the characteristic data measured with the first frequency intervals, and calculates the series resonance frequency, which requires high accuracy, based on the characteristic data measured with the second frequency intervals. Accordingly, the measuring apparatus 1 can measure the parallel resonance frequency and the series resonance frequency with short measurement time.

While this disclosure is described with reference to the embodiments, the technical scope of the disclosure is not limited to the scope of the above-described embodiment. It is apparent to those skilled in the art that various variations and modifications can be made to the above-described embodiments. It is apparent from the claims that such modified embodiments are also included in the scope of this disclosure.

For example, the measuring apparatus 1 may include a control unit including a CPU. The control unit may run a measuring program stored in the storage unit 11 to function as the acquisition unit 12, the input unit 13, the measuring unit 14, the generating unit 15, the calibrating unit 16, the calculating unit 17, and the measurement control unit 18.

The calibrating unit may cause the storage unit to store calibrated information that is obtained by calibrating characteristic data indicative of the characteristic of the crystal unit. The measuring apparatus may further include a calculating unit configured to calculate equivalent circuit constant of the crystal unit based on the calibrated information.

The measuring apparatus may further include a generating unit configured to generate the calibration data generated based on the measurement result measured by the measuring unit with connecting the short-circuit element instead of the crystal unit, associate the calibration data with the measuring condition, and cause the storage unit to store the associated calibration data.

In the measuring apparatus, the input unit may input a measurement signal based on the measuring condition, and the calibrating unit may calibrate the characteristic of the crystal unit using the calibration data corresponding to the measuring condition. In addition, in the measuring apparatus, the storage unit may store at least any one of a frequency of the measurement signal, a level of the measurement signal, and a time interval with which the frequency of the measurement signal changes, as the measuring condition.

In the measuring apparatus, the input unit sequentially inputs a plurality of the measurement signals frequencies of which change per a first period of time into the crystal unit, and the measuring apparatus may further include a measurement control unit configured to: determine whether or not the characteristic of the crystal unit measured by the measuring unit per a second period of time equal to or longer than the first period of time fulfills the predetermined condition, and stop the measurement when the characteristic of the crystal unit fulfills the predetermined condition.

According to a second aspect of this disclosure, a measuring method for measuring the characteristic of a crystal unit is provided, which includes: inputting a measurement signal into the crystal unit; measuring the characteristic of the crystal unit based on an output signal output from the crystal unit with respect to the measurement signal; associating calibration data with measuring condition to measure the characteristic of the crystal unit, and storing the associated data. The calibration data is generated based on a measurement result measured in the measuring step with connecting a short-circuit element instead of the crystal unit; and calibrating the characteristic of the crystal unit measured in the measuring step based on the calibration data.

According to a third aspect of this disclosure, a measuring program is provided, which causes a computer to function as: an input unit configured to input a measurement signal into the crystal unit; a measuring unit configured to measure the characteristic of the crystal unit based on an output signal output from the crystal unit with respect to the measurement signal; a storage unit configured to associate calibration data with a measuring condition to measure the characteristic of the crystal unit, and store the associated data, the calibration data being generated based on a measurement result measured by the measuring unit with connecting a short-circuit element instead of the crystal unit; and a calibrating unit configured to calibrate the characteristic of the crystal unit measured by the measuring unit based on the calibration data.

The measuring apparatus, the measuring method, and the measuring program according to this disclosure successfully reduce a period of time for measuring the characteristics of the crystal unit.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A measuring apparatus for measuring a characteristic of a crystal unit, comprising:
an input unit, being configured to input a measurement signal into the crystal unit;
a measuring unit, being configured to measure the characteristic of the crystal unit based on an output signal output from the crystal unit with respect to the measurement signal;
a storage unit, being configured to associate calibration data with a measuring condition to measure the characteristic of the crystal unit, and store the associated data, the calibration data being generated based on a measurement result measured by the measuring unit with connecting a short-circuit element instead of the crystal unit; and
a calibrating unit, being configured to calibrate the characteristic of the crystal unit measured by the measuring unit based on the calibration data.

2. The measuring apparatus according to claim 1, wherein
the calibrating unit is configured to cause the storage unit to store calibrated information obtained by calibrating characteristic data indicative of the characteristic of the crystal unit, and
the measuring apparatus further includes: a calculating unit, being configured to calculate an equivalent circuit constant of the crystal unit based on the calibrated information.

3. The measuring apparatus according to claim 2, further comprising:
a generating unit, being configured to generate the calibration data generated based on the measurement result measured by the measuring unit with connecting the short-circuit element instead of the crystal unit, associate the calibration data with the measuring condition, and cause the storage unit to store the associated calibration data.

4. The measuring apparatus according to claim 1, wherein
the input unit is configured to input the measurement signal based on the measuring condition, and
the calibrating unit is configured to calibrate the characteristic of the crystal unit using the calibration data corresponding to the measuring condition.

5. The measuring apparatus according to claim 4, wherein
the storage unit stores at least any one of a frequency of the measurement signal, a level of the measurement signal, and a time interval with which the frequency of the measurement signal changes, as the measuring condition.

6. The measuring apparatus according to claim 1, wherein
the input unit is configured to sequentially input a plurality of the measurement signals frequencies of which change per a first period of time into the crystal unit, and
the measuring apparatus further includes: a measurement control unit, being configured to: determine whether or not the characteristic of the crystal unit measured by the measuring unit per a second period of time equal to or longer than the first period of time fulfills the predetermined condition, and stop the measurement when the characteristic of the crystal unit fulfills the predetermined condition.

7. A measuring method for measuring a characteristic of a crystal unit, comprising:
inputting a measurement signal into the crystal unit;
measuring the characteristic of the crystal unit based on an output signal output from the crystal unit with respect to the measurement signal;
associating calibration data with a measuring condition to measure the characteristic of the crystal unit, and storing the associated data, the calibration data being generated based on a measurement result measured by the measuring unit with connecting a short-circuit element instead of the crystal unit; and
calibrating the characteristic of the crystal unit measured by the measuring unit based on the calibration data.

8. A computer-readable storage medium having a measuring program recorded thereon; where the measuring program makes the computer operate as:
an input unit, being configured to input a measurement signal into the crystal unit;
a measuring unit, being configured to measure the characteristic of the crystal unit based on an output signal output from the crystal unit with respect to the measurement signal;
a storage unit, being configured to associate calibration data with a measuring condition to measure the characteristic of the crystal unit, and store the associated data, the calibration data being generated based on a measurement result measured by the measuring unit with connecting a short-circuit element instead of the crystal unit; and
a calibrating unit, being configured to calibrate the characteristic of the crystal unit measured by the measuring unit based on the calibration data.
